(19) United States
(12) Patent Application Publication
(10) Pub. No.: US 2011/0266604 A1
(43) Pub. Date: Nov. 3, 2011

(54) NONVOLATILE MEMORY DEVICE AND METHOD FOR FABRICATING THE SAME

(76) Inventors: Suk-Goo KIM, Gyeonggi-do (KR); Seung-Beck Lee, Seoul (KR); Jun-Hyuk Lee, Seoul (KR); Seul-Ki Oh, Seoul (KR)

(21) Appl. No.: 12/982,049

(22) Filed: Dec. 30, 2010

(30) Foreign Application Priority Data
Apr. 30, 2010 (KR) 10-2010-0040884

(51) Int. Cl. H01L 29/78; H01L 21/8246

(52) U.S. Cl. 257/314; 438/287; 257/E21.679; 257/E29.255

(57) ABSTRACT

A nonvolatile memory device includes a plurality of strings each having vertically-stacked active layers over a plurality of word lines, at least one bit line connection unit vertically formed over one end of the word lines and having a stairway shape, and a plurality of bit lines each coupled to each of a plurality of active regions of the bit line connection unit.

### CROSS-REFERENCE TO RELATED APPLICATIONS

The present application claims priority of Korean Patent Application No. 10-2010-0040884, filed on Apr. 30, 2010, which is incorporated herein by reference in its entirety.

### BACKGROUND OF THE INVENTION

Exemplary embodiments of the present invention relate to memory devices, and more particularly, to a nonvolatile memory device and a method for fabricating the same.

FIG. 1 is a view illustrating a conventional nonvolatile memory device.

Referring to FIG. 1, a three-dimensional memory structure having a gate defined in a vertical direction on a substrate is illustrated. Lithography, fine control and N-type ion implantation are performed to define a decode-type drain select line DSL while stacking dielectric layers and active layers. This is repeated to stack a plurality of layers. The substrate is patterned and etched, and an oxide-nitride-oxide (ONO) layer and a gate material are deposited, thereby forming a three-dimensional memory structure having a gate defined in a vertical direction on a substrate. In the drawing, ‘BL’ denotes a bit line. ‘BLC’ denotes a bit line plug. ‘DSL’ denotes a drain select line. ‘WL’ denotes a word line. ‘SSL’ denotes a source select line. ‘CSL’ denotes a common source line. ‘Vbb’ denotes a body voltage.

In the above structure, string selection is performed as follows. The string selection includes: applying a voltage to each bit line BL connected to each of the string layers; and selecting a desired layer by using a drain select line DSL of a decode-type where all the layers and all the strings are connected in the same direction as the word lines WL. In other words, when a voltage of a bit line BL is applied to all the string layers, one of all the string layers is selected by the drain select line (DSL) of a drain select transistor.

As described above, the conventional method requires an additional photolithography process and an additional implantation process for each layer in order to define a drain select line DSL when stacking dielectric layers and active layers, Therefore, the number of drain select lines DSL increases as a number ‘m’ of layers increases. If ‘n’ is an even number, the layer number ‘m’ increases according to the following equation: m=(n!)/{(n/2)1*(n/2)!}; and if ‘n’ is an odd number, the layer number ‘m’ increases according to the following equation: m=(n!)/[{(n−1)/2)!*{(n+1)/2}1].

### SUMMARY OF THE INVENTION

Exemplary embodiments of the present invention are directed to a nonvolatile memory device and a method for fabricating the same, which can simplify an electrode interconnection process and can reduce the occupation area of drain select lines.

In accordance with an exemplary embodiment of the present invention, a nonvolatile memory device includes a plurality of strings each having vertically-stacked active layers over a plurality of word lines, at least one bit line connection unit vertically formed over one end of the word lines and having a stairway shape, and a plurality of bit lines each coupled to each of a plurality of active regions of the bit line connection unit.

In accordance with another exemplary embodiment of the present invention, a method for fabricating a nonvolatile memory device includes forming a multilayer structure having a plurality of active layers and a plurality of dielectric layers stacked alternately over a plurality of word lines, forming at least one bit line connection unit having stairway shaped active layers by etching one end of the multilayer structure, forming stairway shaped active regions in the bit line connection unit, forming a plurality of bit line plugs each connected to each of the active regions of the bit line connection unit, and forming a plurality of bit lines each connected to each of the bit line plugs.

### BRIEF DESCRIPTION OF THE DRAWINGS

FIG. 1 is a view illustrating a conventional nonvolatile memory device.

FIG. 2A is a circuit diagram of a nonvolatile memory device in accordance with an exemplary embodiment of the present invention.

FIG. 2B is a circuit diagram illustrating a case where any one drain select line is selected.

FIG. 2C is a circuit diagram illustrating a case where any one bit line is selected.

FIGS. 3A to 3J are views illustrating a method for fabricating a nonvolatile memory device in accordance with an exemplary embodiment of the present invention.

FIG. 4 is a view illustrating a nonvolatile memory device in accordance with another exemplary embodiment of the present invention.

FIGS. 5A to 5F are views illustrating a method for forming a stairway bit line connection unit in accordance with an exemplary embodiment of the present invention.

FIG. 6 is a plan view illustrating a plurality of blocks including a stairway bit line connection unit.

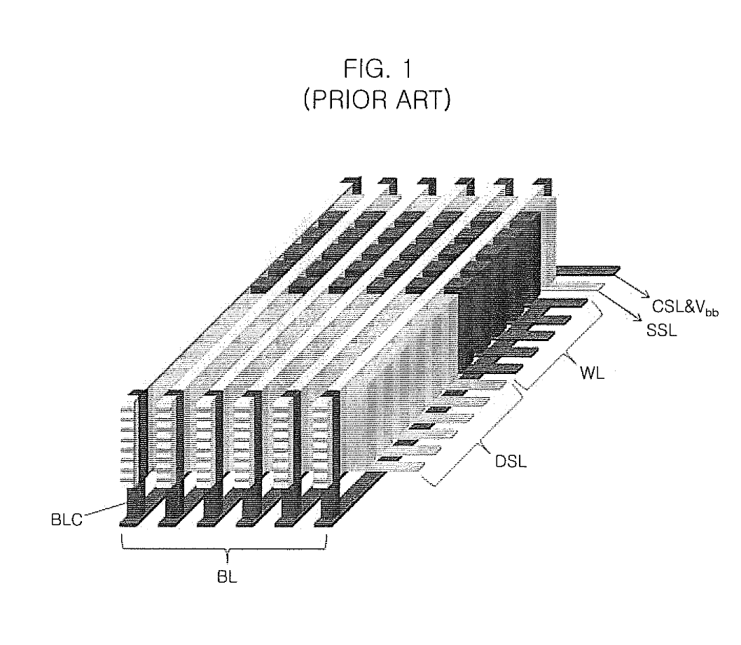

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

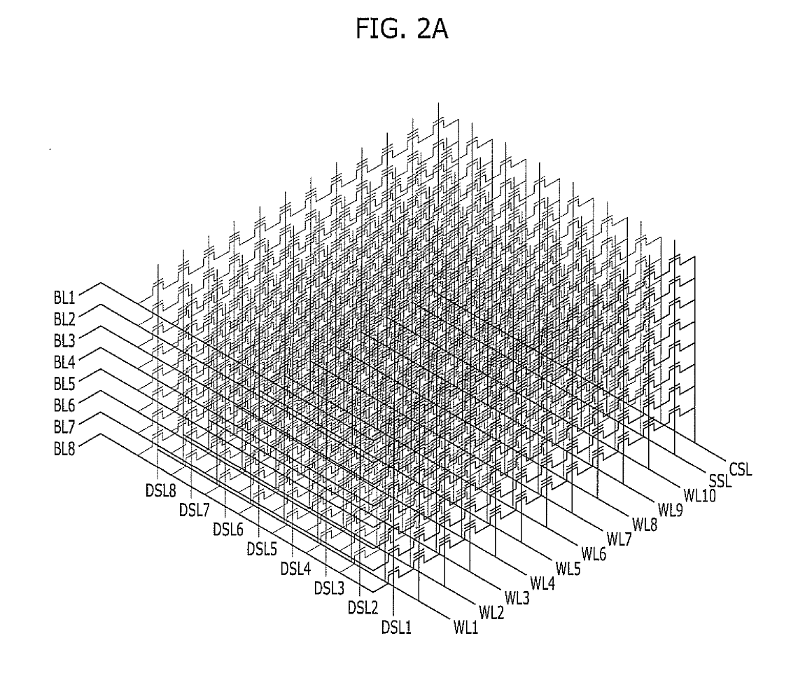

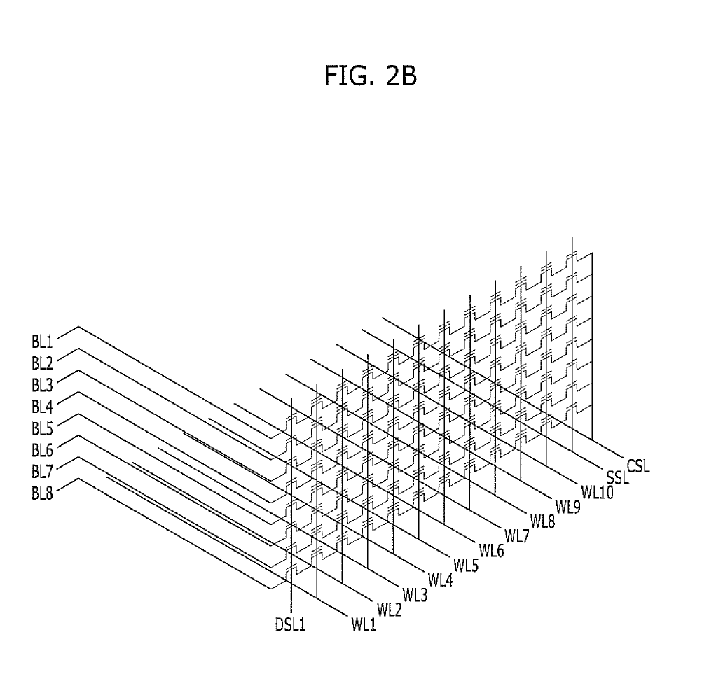

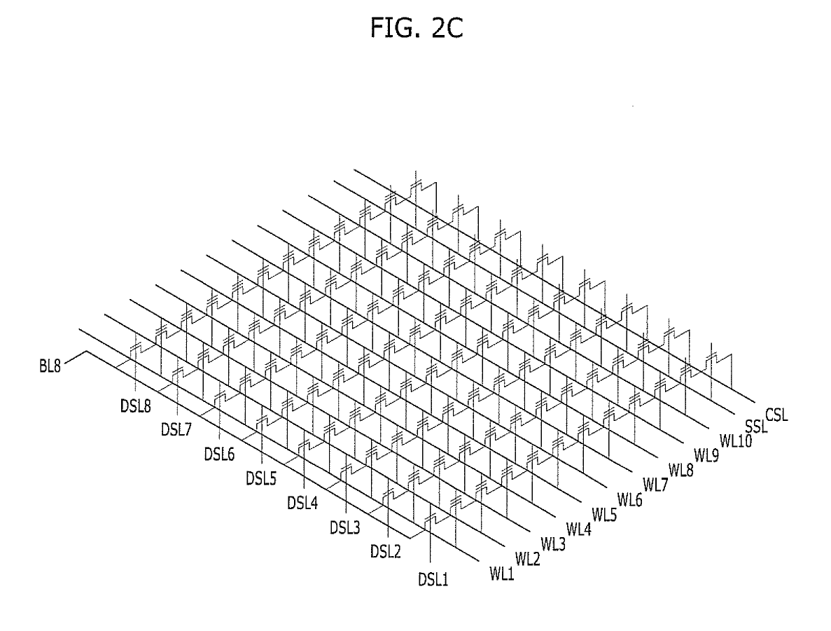

FIG. 2A is a circuit diagram of a nonvolatile memory device in accordance with an exemplary embodiment of the present invention. FIG. 2B is a circuit diagram illustrating a case where any one drain select line is selected. FIG. 2C is a circuit diagram illustrating a case where any one bit line is selected. A drain select line (DSL) is also called a string select line, and a source select line (SSL) is also called a ground select line.

Referring to FIGS. 2A to 2C, a plurality of strings connected to corresponding bit lines BL1-BL8, defined in a horizontal direction on a substrate, are formed. Further, drain select lines DSL1-DSL8, defined in a vertical direction on the substrate, are formed. Dielectric layers and active layers are alternately stacked to form a plurality of layers. The stacked layers are patterned and etched to define the bit lines BL1-BL8 connecting all the strings of the same active layer. Each gate insulating layer material is deposited, and a drain select line plug, a word line plug and a source select line plug are defined. The drain select line plug becomes a drain select gate, the word line plug becomes a gate, and the source select line plug becomes a source select gate. Accordingly, a bit line voltage may be applied to each layer, and any one of the drain select lines is selected to select only one string. ‘CSL’ denotes a common source line, and ‘WL1-WL10’ denotes word lines.

The following exemplary embodiments of the present invention describe a memory structure with eight active layers. However, the present invention is not limited thereto. It should be understood by one of ordinary skill in the art that the number of the active layers may be increased or decreased.

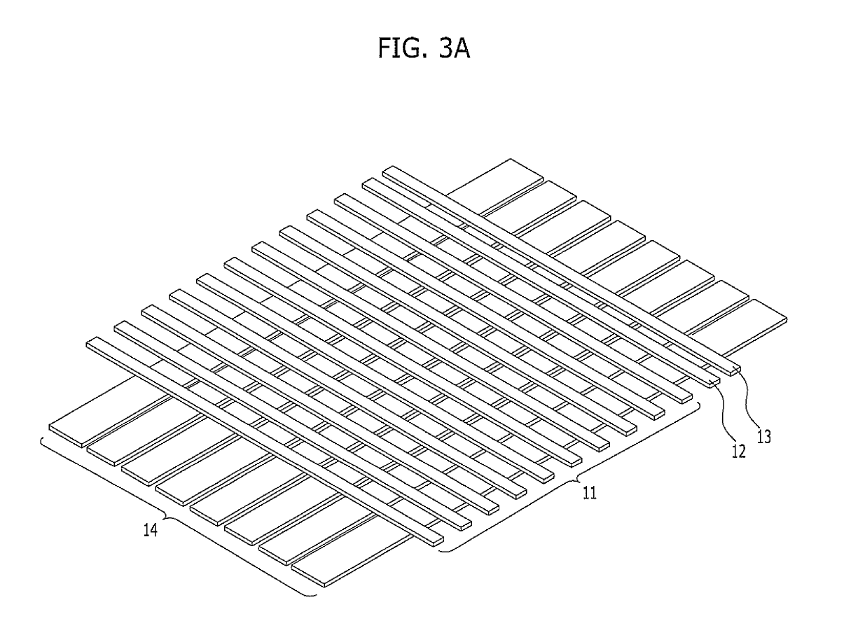

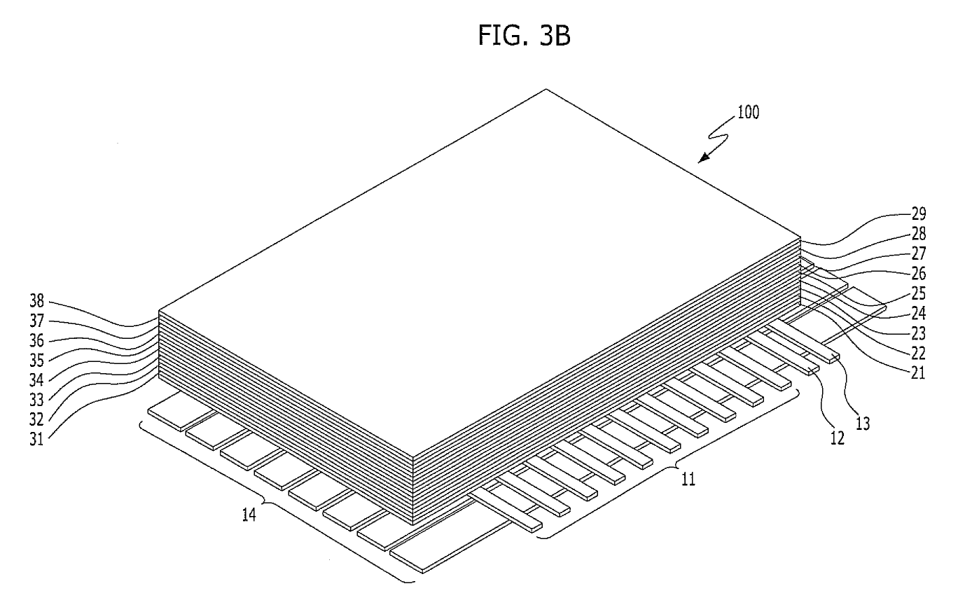

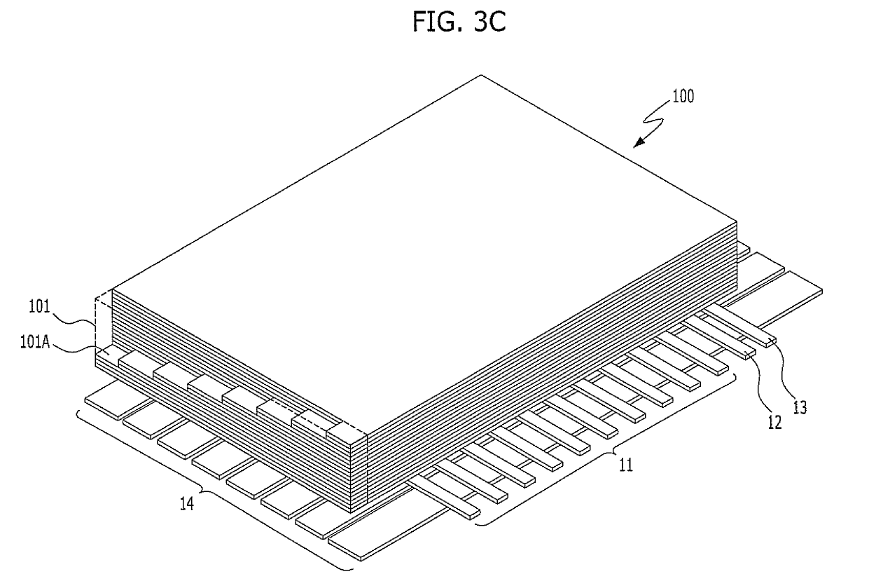

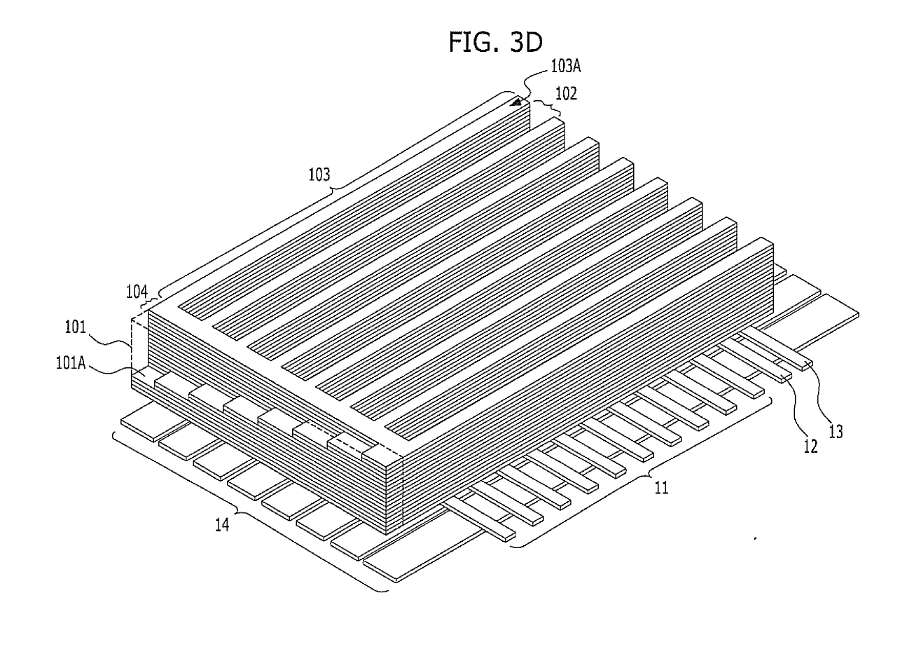

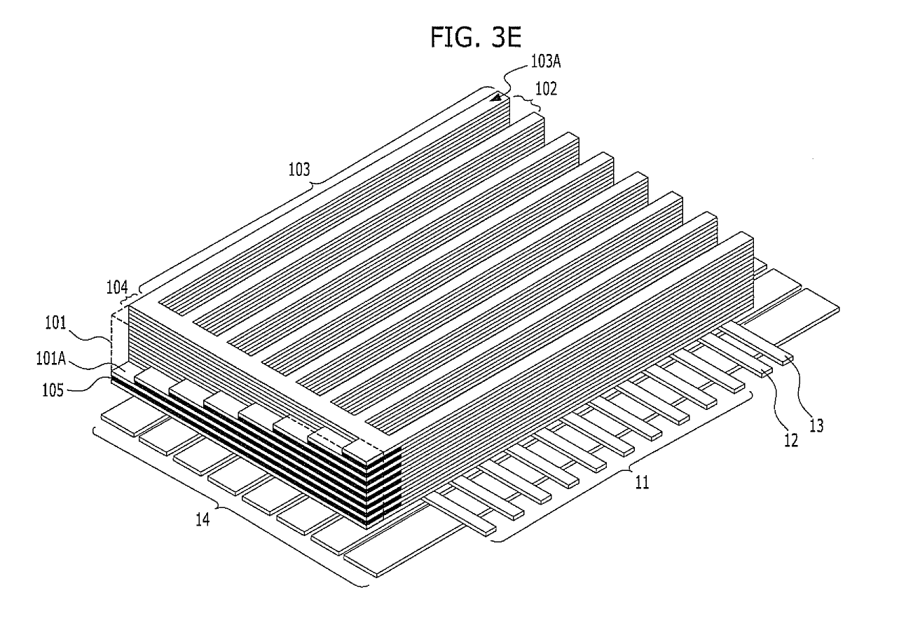

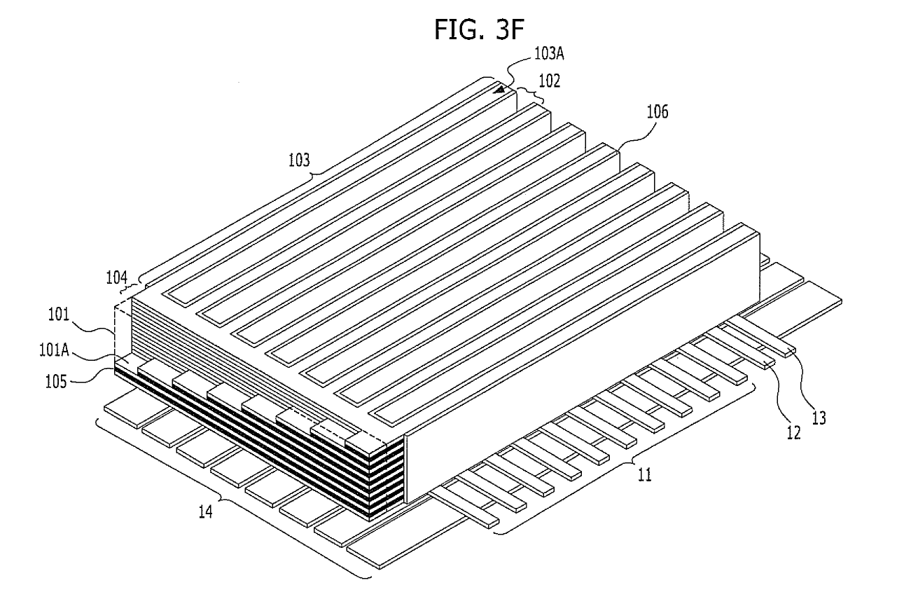

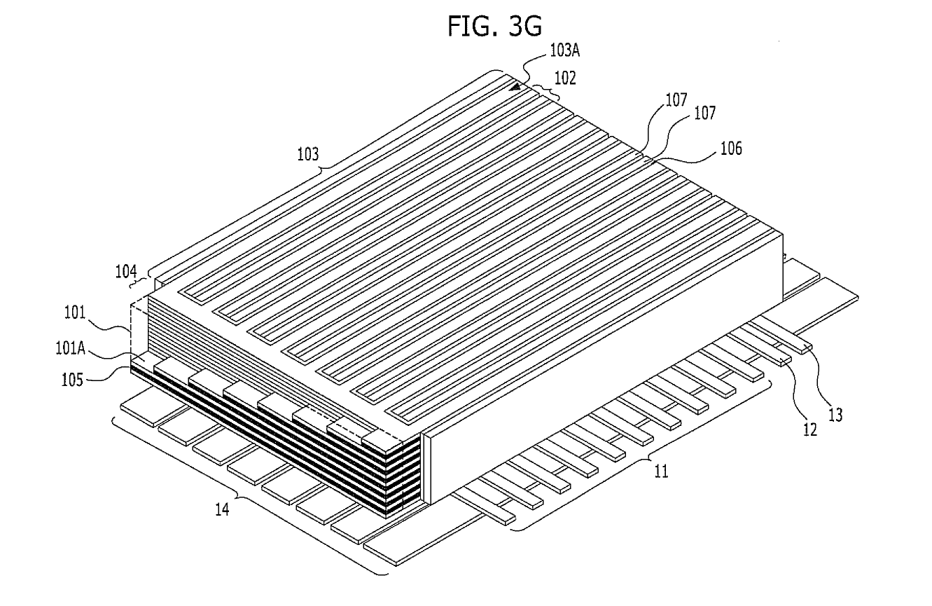

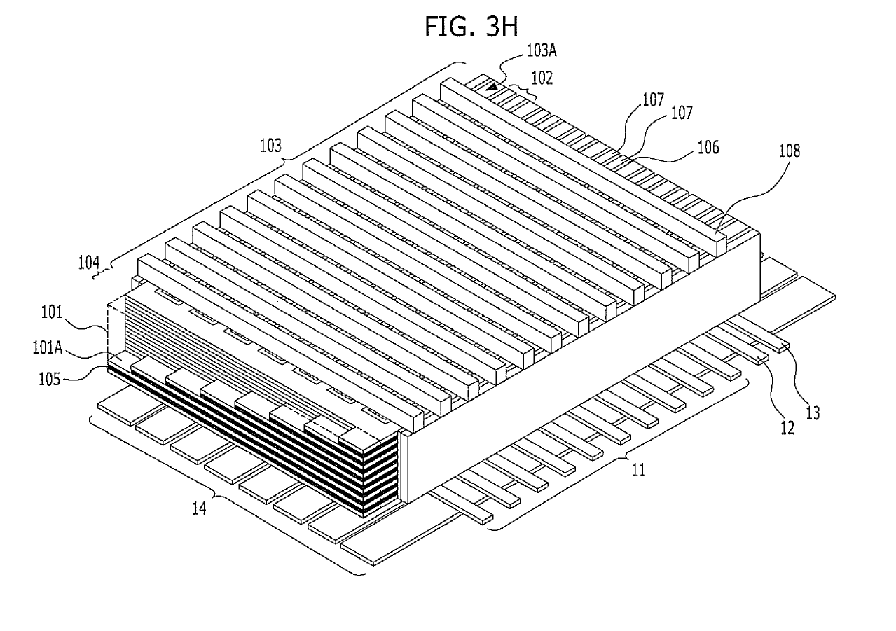

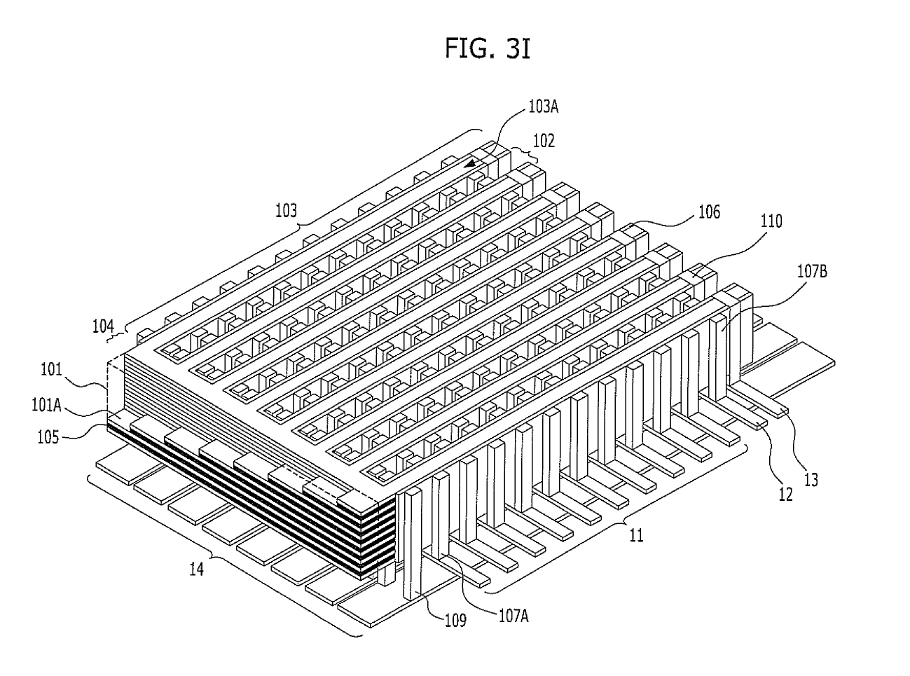

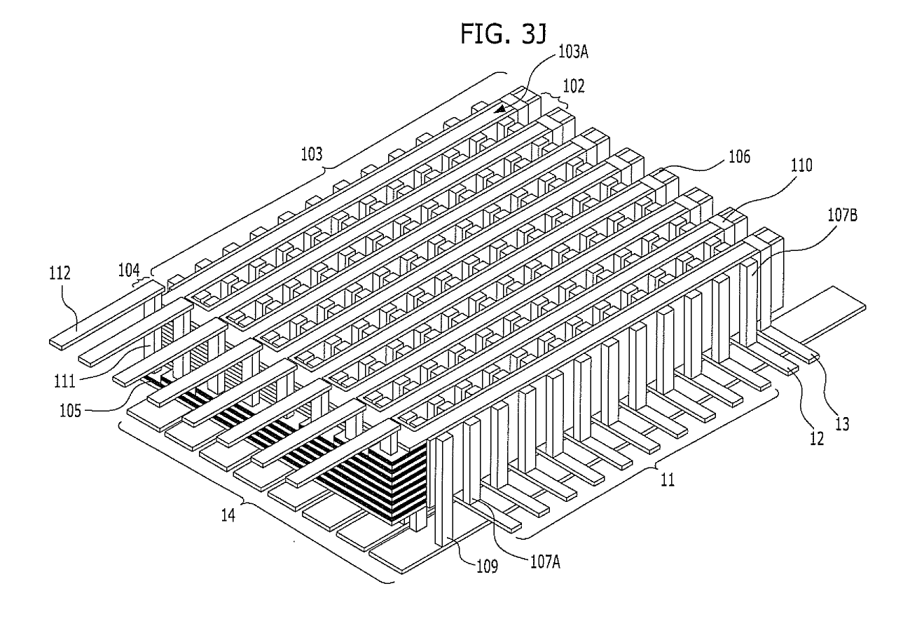

FIGS. 3A to 3J are views illustrating a method for fabricating a nonvolatile memory device in accordance with an exemplary embodiment of the present invention.

Referring to FIG. 3A, an electrode interconnection process is performed to form a plurality of word lines (WL) 11, a source select line (SSL) 12, a common source line (CSL) 13, and a plurality of drain select lines (DSL) 14 on a substrate (not illustrated). The electrode interconnection process may be performed after completion of fabrication of a memory array. The word lines 11, the source select line 12 and the common source line 13 extend in a first direction, and the drain select lines 14 extends in a second direction. Ideally, the first direction and the second direction are perpendicular to each other. The word lines 11, the source select line 12, and the common source line 13 are formed to have approximately the same width. The drain select lines 14 may be formed to be wider than the word lines 11, the source select line 12, and the common source line 13. The word lines 11, the source select line 12, and the common source line 13 are formed on the same plane, and the drain select lines 14 are insulated by a dielectric layer (not illustrated) formed during the formation of the word lines 11, the source select line 12, and the common source line 13. The drain select lines 14 may be formed before the other lines are formed.

Referring to FIG. 3B, a multilayer structure 100 having dielectric layers 21, 22, 23, 24, 25, 26, 27, 28 and 29 and active layers 31, 32, 33, 34, 35, 36, 37 and 38, which are formed alternately and serve as a base for a memory array, are formed. In an exemplary embodiment as shown in FIG. 3B, in the formation of the multilayer structure 100, the dielectric layer is stacked nine times (the first to ninth dielectric layers), and the active layer is stacked eight times (the first to eighth active layers). The first to ninth dielectric layers 21, 22, 23, 24, 25, 26, 27, 28 and 29 may include a silicon dioxide (SiO₂). The first to eighth active layers 31, 32, 33, 34, 35, 36, 37 and 38 may include a polycrystalline silicon doped with p-type impurities. The materials of the first to ninth dielectric layers 21, 22, 23, 24, 25, 26, 27, 28 and 29 and the first to eighth active layers 31, 32, 33, 34, 35, 36, 37 and 38 are not limited to a silicon dioxide and a polycrystalline silicon. That is, the first to ninth dielectric layers 21, 22, 23, 24, 25, 26, 27, 28 and 29 and the first to eighth active layers 31, 32, 33, 34, 35, 36, 37 and 38 may be formed of other materials. The uppermost ninth dielectric layer 29 is formed to such a thickness as not to expose the eighth active layer 38 thereunder until the subsequent plug forming process. The first to eighth active layers 31, 32, 33, 34, 35, 36, 37 and 38 act as a channel of a memory cell transistor.

Referring to FIG. 3C, a stairway structure 101 is formed without to allow for the connection of the first to eighth active layers 31, 32, 33, 34, 35, 36, 37 and 38. FIG. 3C illustrates one block where the stairway structure 101 is formed. However, as described below, the stairway structure 101 may be formed in each of four blocks. The stairway structure 101 is provided at one end of the multilayer structure 100 to allow bit lines to be connected in a subsequent process. The stairway structure 101 has a total of eight stairs 101A. The number of the stairs 101A is equal to the number of the active layers. The stairway structure 101 is ascended stepwise in a direction toward the uppermost active layer.

The stairway structure 101 gradually steps down from the uppermost stair on one side of the stairway structure 101 to the lowermost stair on the other side of the stairway structure 101. All the stairs may have the same surface area.

According to the above description, the stairway structure 101 is formed in an area where bit line connections are subsequently formed. Thus, hereinafter, the stairway structure 101 is called a stairway bit line connection unit 101.

A cell process is performed subsequently. A passivation/planarization process may be performed before the performing of the cell process. Hereinafter, the reference numerals of the active layers and the dielectric layers will be omitted, and they will be referred to collectively as a multilayer structure 100. The word lines 11, the bit line connection unit 101, and the multilayer structure 100 are insulated each others by the lowermost dielectric layer of the multilayer structure 100.

The multilayer structure 100 in FIG. 3D may belong to any one of a number of memory blocks.

As illustrated in FIG. 3D, the multilayer structure 100 is etched to form one string layer 103 per bit line, thereby forming an etched portion 102. Due to the etched portion 102, a plurality of strings 103A on the same string layer 103 become independent of each other. That is, each string layer 103 has a plurality of strings 103A extending in the horizontal direction (i.e., a string layer 103 refers to the plurality of strings 103A in the same plane), and a plurality of string layers 103 are stacked in the vertical direction. The number of the string layers 103 is equal to the number of the active layers.

The etched portion 102 must not completely contact the stairway bit line connection unit 101. That is, a certain unetched area between the stairway bit line connection unit 101 and the etched portion 102 remains. This unetched area is called a connection unit 104. That is, the connection unit 104 connected between the bit line connection unit 101 and the plurality of strings 103 is formed when the multilayer structure 100 is etched.

As described above, a mask (not illustrated) is used to form the etched portion 102. The mask covers the bit line connection unit 101 and the connection unit 104. The mask may be patterned in the shape of lines to divide the multilayer structure 100 into a plurality of strings 103A. The strings 103A of the same string layer 103 form a comb-shape because of the connection unit 104. The comb-shaped string layer 103 is stacked as many times as the number of the active layers. The drain select lines 14 have a one-to-one correspondence with the string layers 103. As shown in FIG. 3D, the strings 103A are vertically stacked and a plurality of stacks are formed in parallel. Further, the strings 103A of the same stack are simultaneously selected by one of the drain select lines 14.

Although not illustrated in the drawings, the active layer of the string 103A acts as a channel of a source select transistor, a drain select transistor and a memory cell transistor. Thus, one string 103A has a structure in which a plurality of memory cell transistors are horizontally connected in series.

Referring to FIG. 3E, in order to connect the strings 103A to bit lines, the active layers of the stairway bit line connection unit 101 are replaced by a replacement unit 105. The active layers have a high resistance if not affected by an external electric field. Thus, after the bit lines are connected, the resistance of the active layers of the connection unit 104 and the stairway bit line connection unit 101 may be lowered in order to secure a smooth charge flow. To this end, after the active layers of the connection unit 104 and the stairway bit line connection unit 101 are removed, the replacement unit 105 is formed of a high-conductive material such as a metal (e.g., tungsten, tantalum) or a heavily-doped N⁺ polycrystalline silicon. The replacement unit 105 includes a material that can be deposited and etched while having a high conductivity. The resistance may also be lowered by ion implantation, as well as by the replacement unit 105. The connection unit 104 between the strings 103A and the bit line connection unit 101 has such a size as to compensate the active layer replacement of the bit line connection unit 101. If the replacement unit 105 is formed of a metal such as tungsten or tantalum, an additional thermal process may be performed to form a silicide in a contact region between the active layers of the string layer 103 and the replacement unit 105, or a heavily-doped N⁺ polycrystalline silicon may be deposited, in order to secure the ohmic contact with the active layer of the string layer 103. Also possible is a method by lithography and doping after active layer deposition.

Referring to FIG. 3F, a tunneling insulating layer, a charge trapping layer and a blocking insulating layer are sequentially deposited on the sidewall of the etched portion to form a gate insulating layer 106. Dielectric materials including SiO₂, Al₂O₃, HfN and HfAlO, or high-k dielectric materials may be used to form the tunneling insulating layer or the blocking insulating layer. Dielectric materials including Si₃N₄, HfAlO, Al₂O₃, AlN and HfSiO, or high-k dielectric materials may be used to form the charge trapping layer. If the active layer includes silicon, the tunneling insulating layer may be formed through a thermal oxidation process. The tunneling insulating layer, the charge trapping layer or the blocking insulating layer may be formed through a thermal oxidation process by depositing a material such as aluminum (AL) or silicon (Si).

After the electrode interconnection process is performed as illustrated in FIG. 3A, the gate insulating layer 106 deposited on the bottom surface of the etched portion is etched to obtain an electrical short with the word lines 11, the source select line 12, the common source line 13, and the drain select line 14 via plugs that are subsequently formed. Meanwhile, if the electrode interconnection process is performed lastly, the etching of the gate insulating layer 106 may be simultaneously performed.

Referring to FIG. 3G, a plug material 107 is gap-filled in the etched portion 102. Herein, the etched portion 102 is not completely filled, but is filled to such a degree as to secure the electrical short. The plug material 107 deposited on the bottom surface of the etched portion 102 is etched. A dielectric material (not illustrated) is filled between the plug materials 107. Thereafter, the mask is removed.

As described above, the mask used to form the etched portion remains during the processes of forming the gate insulating layer 106 and the plug material 107. Thus, the gate insulating layer 106 and the plug material 107 are also formed on the mask. However, the illustration of them is omitted because they are lifted off when the mask is removed. A planarization process may be performed after the removing of the mask.

Referring to FIG. 3H, a plug mask 108 is formed. The plug mask 108 has the shape of lines that extend in the same direction as the word lines 11. The lines of the plug mask 108 may have the same width as the word lines 11.

Referring to FIG. 31, the plug material 107 at a portion not covered by the plug mask 108 is removed. Accordingly, a plurality of plugs 107A, 107B and 109 are formed. ‘107A’ denotes word line plugs connected to each of the word lines 11. ‘107B’ denotes source select line plugs connected to the source select line 12. ‘109’ denotes drain select line plugs connected to each of the drain select lines 14. Although not illustrated in the drawings, a dielectric material may be filled after the forming of the plugs 107A, 107B and 109. Herein, neighboring drain select line plugs 109 are electrically isolated from each other. The word line plugs 107A connected to the word lines 11 serve as control gate electrodes. Accordingly, the control gate electrodes have a vertical structure that simultaneously selects corresponding strings 103A of all the string layers 103. The source select line plugs 107B connected to the source select line 12 serve as gate electrodes of the source select transistors.

After forming the plugs 107A, 107B and 109, the plug mask 108 is removed and a through common source line plug 110 connected to the common source line 13 is formed. The common source line plug 110 pierces through the multilayer structure 100. A planarization process may be performed after the removing of the plug mask 108.

Referring to FIG. 3J, bit lines 112, connected to each active layer of the bit line connection unit 101, are formed. Each of the bit lines 112 is connected through a bit line plug 111 to each active layer. The bit lines 112 extend in the direction perpendicular to the direction of the word lines 11.

As described above, a bit line 112 is connected to each of the strings 103A of the same string layer 103. Because the string layer 103 having a plurality of strings 103A has multiple layers in the vertical direction, the nonvolatile memory device of the present invention has a multilayer string structure where the string layer 103 having a plurality of strings 103A forms a multilayer. Also, one string layer 103 is connected to each bit line 112. Also, because the drain select lines 14 are connected to the vertical plugs 109, the strings 103A of all the vertically-stacked string layers 103 can be simultaneously selected.

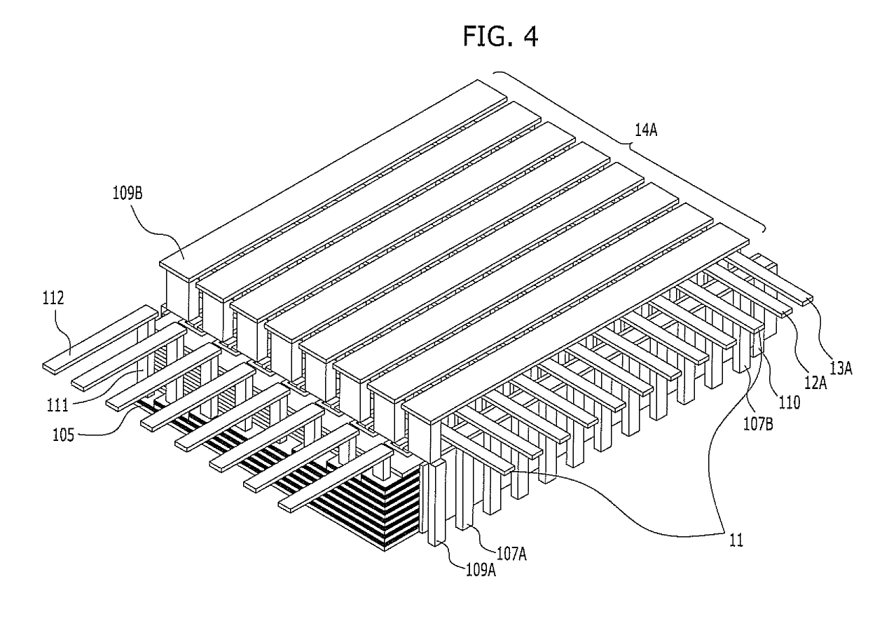

FIG. 4 is a view illustrating a nonvolatile memory device in accordance with another exemplary embodiment of the present invention, which is different from the structure of FIG. 3J in terms of electrode interconnection forming order.

Referring to FIG. 4, word lines 11, a source select line 12A and a common source line 13A are formed after plugs 107A and 107B and through plugs 10 are formed. Also, a drain select line 14A is formed after a bit line 112 is formed. Plugs 109A connected to the drain select lines 14A are formed simultaneously with the other plugs 107A and 107B.

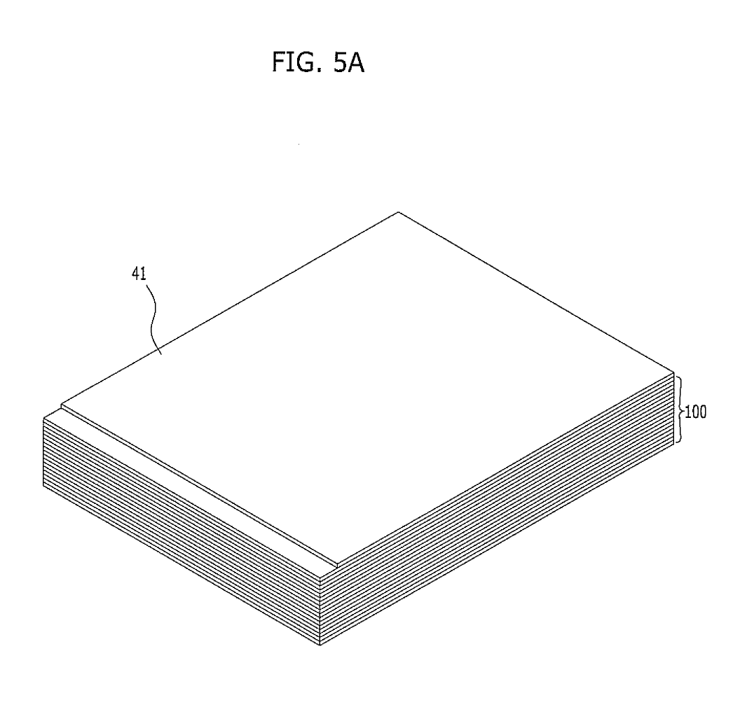

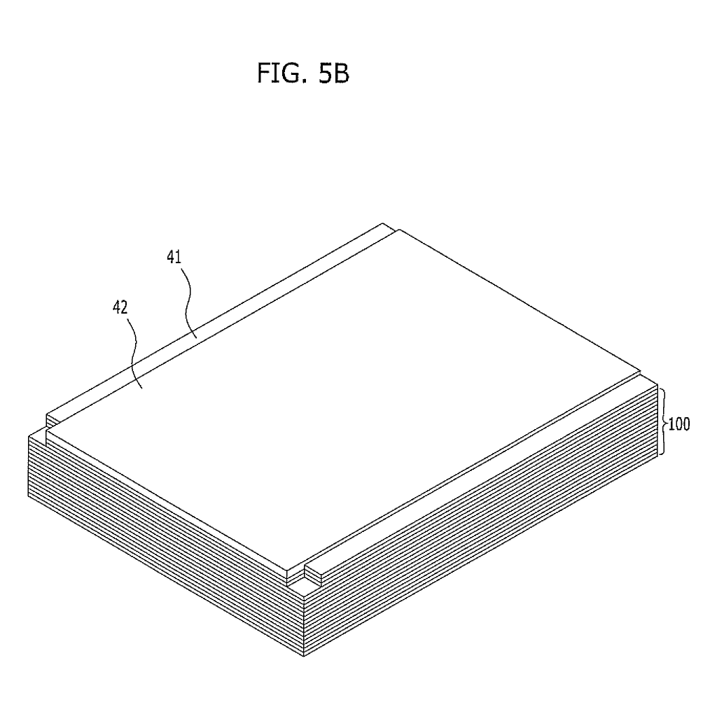

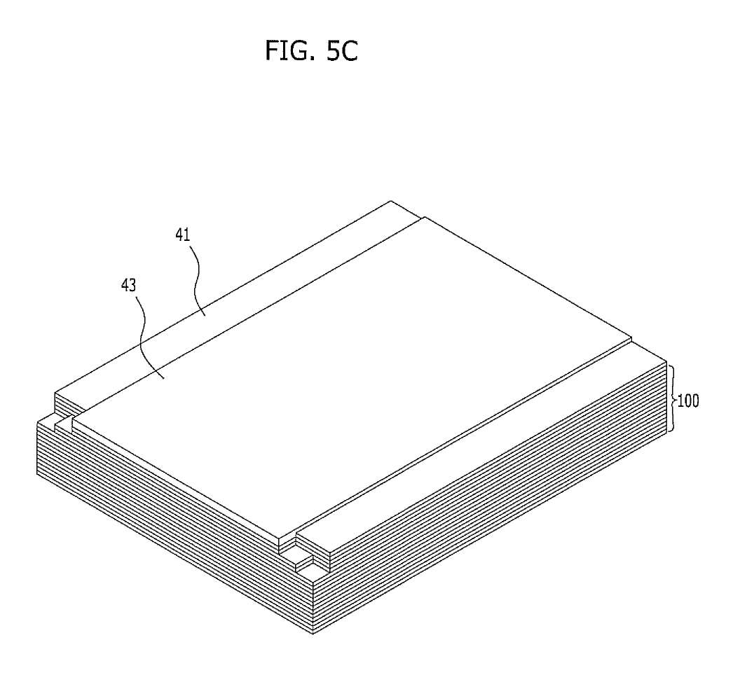

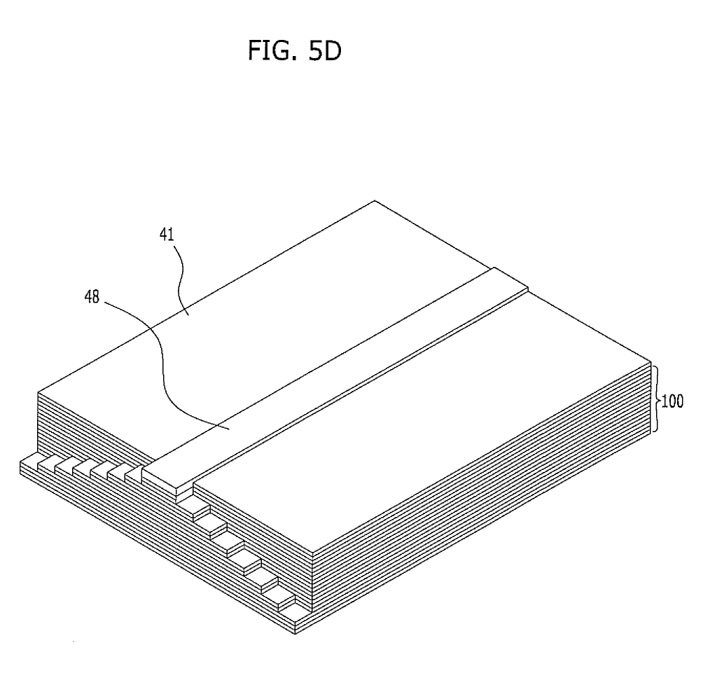

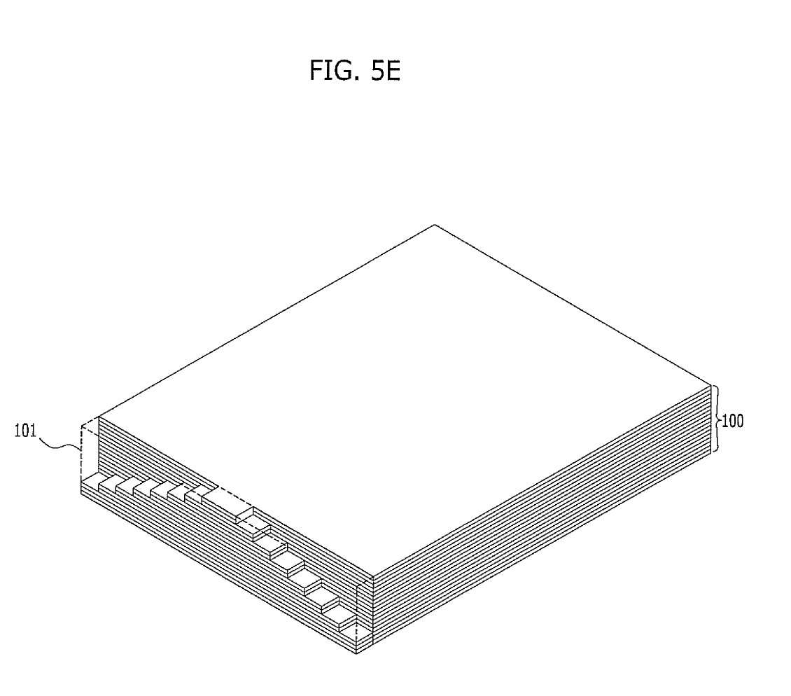

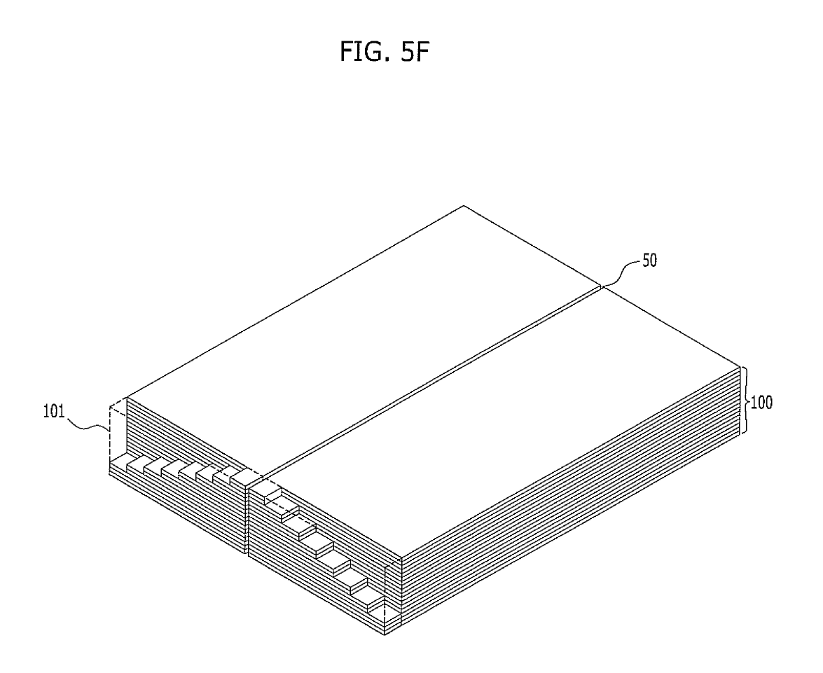

FIGS. 5A to 5F are views illustrating a method for forming a stairway bit line connection unit in accordance with an exemplary embodiment of the present invention.

Hereinafter, the active layers and the dielectric layers constituting the multilayer structure 100 are the same as those of FIG. 4B. For clarity, the reference numerals of the active layers and the dielectric layers are omitted.

Referring to FIG. 5A, a photoresist layer is deposited on the ninth dielectric layer of the multilayer 100, and it is patterned by exposure and development to form a first mask 41. The first mask is formed by patterning a region intended for the bit line connection unit. The other portion of the multilayer structure 100, except the bit line connection unit, is covered by the first mask 41.

Referring to FIG. 5B, a photoresist layer is deposited on the resulting structure including the first mask 41, and it is patterned by exposure and development to form a second mask 42. The second mask 42 is patterned such that both side edges of the bit line connection unit are opened with a predetermined size. Thus, the second mask 42 exposes the first mask 41 to a predetermined size in the first direction, and extends in the second direction to cover a portion of the bit line connection unit. Accordingly, a region at both side edges of the bit line connection unit, which is not covered by either the first mask 41 or the second mask 42, is exposed.

Using the first mask 41 and the second mask 42 as an etch barrier, the ninth dielectric layer of the multilayer structure 100 is etched. At this point, the eighth active layer under the ninth dielectric layer is used as an etch stop layer. The eighth active layer is etched after the etching of the ninth dielectric layer. At this point, the eighth dielectric layer is used as an etch stop layer.

Referring to FIG. 5C, a third mask 43 is formed. The third mask 43 is formed by slimming the second mask 42. Also, the third mask 43 may be formed by stripping the second mask, depositing a photoresist layer and performing an exposure/development process on the resulting structure. The third mask 43 is patterned to have a smaller width than the second mask 42. The third mask 43 has a reduced size in the first direction, and maintains the width in the second direction. In this way, by forming the third mask 43 narrower than the second mask 42, a region at both side edges of the bit line connection, which is not covered by either the first mask 41 or the third mask 43, is exposed.

Using the first mask 41 and the third mask 43 as an etch barrier, the ninth and eighth dielectric layers of the multilayer 100 are etched. At this point, the eighth and seventh active layers are used as an etch stop layer. The eighth and seventh active layers are etched. At this point, the eighth and seventh dielectric layers are used as an etch stop layer.

As described above, the process of forming the third mask 43 by performing a slimming or additional mask process on the second mask 42 while leaving the first mask 41 is repeated several times to form the stairway bit line connection unit.

FIG. 5D illustrates the final result where the stairway bit line connection unit is formed. Because the multilayer structure 100 includes eight active layers, the stairway bit line connection unit 101 has eight stairs.

The final mask 48 used to form the last stair includes a mask formed by slimming the second mask 42. Also, the final mask 48 may be formed by performing a mask process several times.

Referring to FIG. 5E, the final mask 48 is removed. Two stairway bit line connection units 101 are formed at one end of the multilayer structure 100.

Referring to FIG. 5F, at least one slit 50 is formed such that the multilayer structure 100 is divided into more than two independent blocks after the at least one bit line connection unit 101 is formed. Accordingly, the at least one slit 50 divides the multilayer structure 100 including the at least one bit line connection unit 101. The bit line connection units are symmetrically formed with respect to the slit 50. By forming the at least one slit 50, an unnecessary read/write disturbance can be reduced. The lowermost dielectric layer of the multilayer structure 100 is etched when the slit 50 is formed.

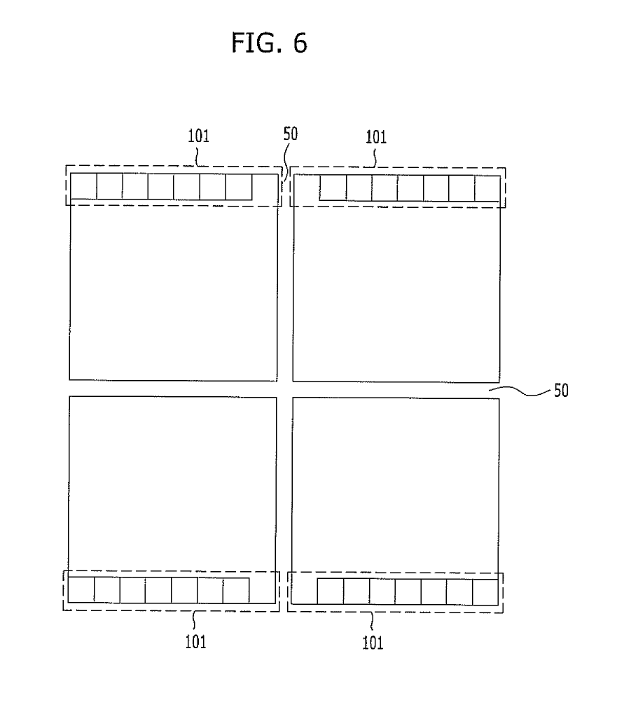

FIG. 6 is a plan view illustrating a plurality of blocks including a stairway bit line connection unit.

Referring to FIG. 6, the stairway bit line connection unit 101 may be formed at opposite ends of the multilayer structure 100. In this case, the slit 50 may be formed in the shape of a cross. When the slit 50 has a cross shape, the multilayer structure 100 is divided to form four blocks. Therefore, stairway bit line connection units 101 are symmetrically formed at opposite ends of the multi structure 100.

In a memory array according to the embodiments of the present invention, a method of selecting a single cell is as follows. Referring to FIGS. 2A to 2C illustrating the circuit diagram of the memory array of the present invention, one bit line is selected and one of the drain select lines is operated to select one string. In the selected string, a read/write operation is performed by applying a voltage to a word line. Meanwhile, a read/write operation is not performed on the unselected string.

As described above, the present invention can simplify the electrode interconnection of a three-dimensional nonvolatile memory device having a vertical control gate electrode capable of implementing high integration.

Also, the bit line connected to all the strings of the same string layer is formed to be perpendicular to the drain select line configured to simultaneously select the multilayer strings. Therefore, even when the number of stacked active layers increases, the integration density can be improved because there is no increase in the occupation area of the drain select line.

In addition, when compared to the fabrication process of a decode-type drain select line structure, the present invention need not perform additional photolithography, fine control and ion implantation processes for definition of the drain select line in the stacking process. Therefore, the present invention is more advantageous in terms of cost reduction as the number of stacked layers increases.

While the present invention has been described with respect to the specific embodiments, it will be apparent to those skilled in the art that various changes and modifications may be made without departing from the spirit and scope of the invention as defined in the following claims.

What is claimed is:

1. A nonvolatile memory device comprising:
a plurality of strings each having vertically-stacked active layers over a plurality of word lines;
at least one bit line connection unit vertically formed over one end of the word lines and having a stairway shape; and
a plurality of bit lines each coupled to each of a plurality of active regions of the bit line connection unit.

2. The nonvolatile memory device of claim 1, wherein the each bit line is coupled to all strings of the same active layer.

3. The nonvolatile memory device of claim 1, wherein the plurality of strings are extended in the same direction as the bit lines.

4. The nonvolatile memory device of claim 1, wherein the number of stairs of the bit line connection unit having the stairway shape is equal to the number of the active layers.

5. The nonvolatile memory device of claim 4, wherein the bit line connection unit having the stairway shape is ascended stepwise in a direction toward a uppermost active region of the bit line connection unit.

6. The nonvolatile memory device of claim 4, wherein a surface area of the each stairs of the bit line connection unit having the stairway shape is the same.

7. The nonvolatile memory device of claim 1, wherein the plurality of strings is formed more than one independent block divided by at least one slit.

8. The nonvolatile memory device of claim 7, wherein the bit line connection units are symmetrically formed with respect to the slit.

9. The nonvolatile memory device of claim 1, further comprising
a plurality of bit line plugs each connected between each of active regions of the bit line connection unit having the stairway shape and each of the bit lines.

10. The nonvolatile memory device of claim 1, wherein the each of active regions of the bit line connection unit having the stairway shape is formed of a high-conductive metal or a heavily-doped N⁺ polycrystalline silicon.

11. The nonvolatile memory device of claim 10, further comprising:
a silicide layer formed between the each of the active regions of the bit line connection unit having the stairway shape and the each of the bit line plugs when the each of active regions of the bit line connection unit having the stairway shape is formed of the high-conductive metal.

12. The nonvolatile memory device of claim 1, wherein the word lines and the bit line connection unit are insulated each other.

13. A method for fabricating a nonvolatile memory device, comprising:
forming a multilayer structure having a plurality of active layers and a plurality of dielectric layers stacked alternately over a plurality of word lines;
forming at least one bit line connection unit having stairway shaped active layers by etching one end of the multilayer structure;
forming stairway shaped active regions in the bit line connection unit;
forming a plurality of bit line plugs each connected to each of the active regions of the bit line connection unit; and
forming a plurality of bit lines each connected to each of the bit line plugs.

14. The method of claim 13, wherein the forming of the stairway shaped active regions in the bit line connection unit comprises:
removing the each of the stairway shape active layers of the bit line connection unit; and
forming a high-conductive metal or a heavily-doped N⁺ polycrystalline silicon where the each removed active layers of the bit line connection unit.

15. The method of claim 14, further comprising
forming a silicide layer formed between the each of stairway shaped the active regions of the bit line connection unit and the each of the bit line plugs when the stairway shaped active regions of the bit line connection unit are formed of the high-conductive metal.

16. The method of claim 13, wherein the forming of the stairway shaped active regions in the bit line connection unit comprises
performing an ion implantation onto the each of the stairway shaped active layers of the bit line connection.

17. The method of claim 13, further comprising, after the forming of at least one bit line connection unit:
forming trenches by etching the multilayer structure; and
forming a plurality of strings by forming a tunneling insulating layer, a charge trapping layer, a blocking insulating layer, a control gate electrode over sidewalls of the trenches.

18. The method of claim 17, further comprising
forming a connection unit connected between the bit line connection unit and the plurality of strings when the forming of the trenches.

19. The method of claim 13, further comprising:
forming at least one slit dividing the multilayer structure to more than two independent blocks after the forming of at least one bit line connection unit.

20. The method of claim 19, wherein the bit line connection units are symmetrically formed with respect to the slit.

21. The method of claim 13, wherein the word lines, the bit line connection unit, and the multilayer structure are insulated each others by a lowermost dielectric layer of the multilayer structure.
